(19) United States
(12) Patent Application Publication
(10) Pub. No.: US 2020/0278474 A1
(43) Pub. Date: Sep. 3, 2020

(54) MODELING COMPLEX BASIN FILL UTILIZING KNOWN SHORELINE DATA

(71) Applicant: Landmark Graphics Corporation, Houston, TX (US)

(72) Inventors: William Clayton Ross, Littleton, CO (US); Kurt Alan Ranzinger, Erie, CO (US)

(21) Appl. No.: 16/651,013

(22) PCT Filed: Dec. 29, 2017
(86) PCT No.: PCT/US2017/069010

§ 371 Date: Mar. 26, 2020

(51) Int. Cl. G01V 99/00; G06F 30/20; G06Q 50/02; G06Q 10/04

(52) U.S. Cl. CPC G01V 99/005; G06Q 10/04; G06Q 50/02; G06F 30/20

(57) ABSTRACT

The disclosure provides a method of generating a basin fill model using a set of known paleogeographic characteristic parameters, for a specified basin location and time interval. The basin fill model can be used to assist in predicting the location of submarine fan deposits containing commercially valuable hydrocarbons or minerals. The generated models and predicted locations can be used in a well system operation plan. A computer program product is also disclosed that can retrieve sets of known paleogeographic data and generate multiple interim models and parameters that can be used for further predictions on where, and at what depth, valuable deposits may be found. Addi-tionally, a basin fill modeling system is disclosed that can retrieve and store known characteristic parameters for various geographic locations and time periods and utilize those characteristic parameters in algorithms to generate basin fill models and to predict where valuable submarine fan deposits are located.

### BACKGROUND

Building three-dimensional (3D) models of the earth helps exploration geologists better understand and predict the distribution of economically important rock types, including source, seal, and reservoir deposits. One type of geological formation that is difficult to predict is a submarine fan deposit, also known as an abyssal fan, a deep-sea fan, and underwater delta. Forward stratigraphic modeling is one method being used to determine submarine fan depositions that emphasizes the modeling of sea level changes as the key determinant of submarine fan deposition. Multiple iterations of the resultant models are needed to refine the model to a useful state. Since there is a significant number of unknowns in this modeling, the iterations and computational power required to achieve a usable result is high. Accordingly, technology that can reduce the exploration risk and cost in predicting submarine fan reservoirs in frontier and some mature basins would be beneficial.

### BRIEF DESCRIPTION

Reference is now made to the following descriptions taken in conjunction with the accompanying drawing, in which:

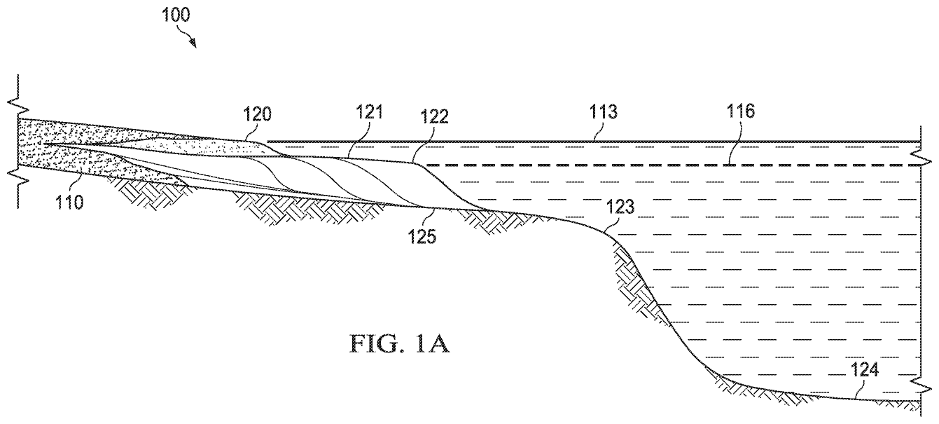

FIG. 1A illustrates an example diagram demonstrating a basin profile of equilibrium for a non-marine and shallow marine environment;

FIG. 1B illustrates an example diagram demonstrating a basin profile of equilibrium propagating into a deep marine environment;

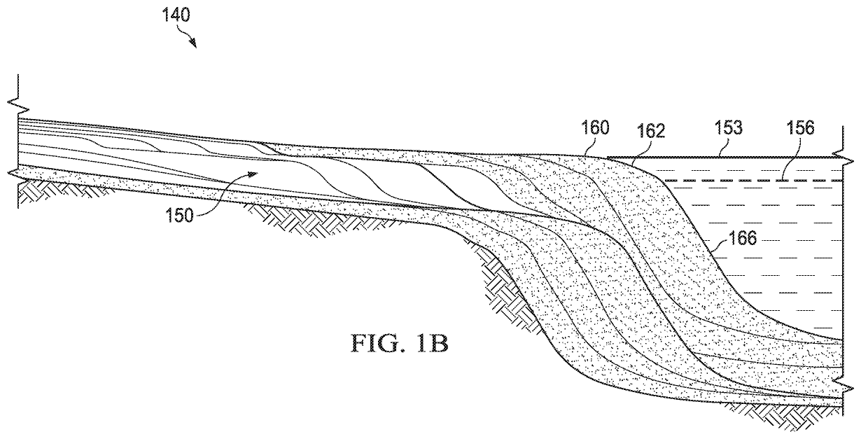

FIG. 2 illustrates an example diagram of a graph demonstrating sedimentary layers extending under sea level;

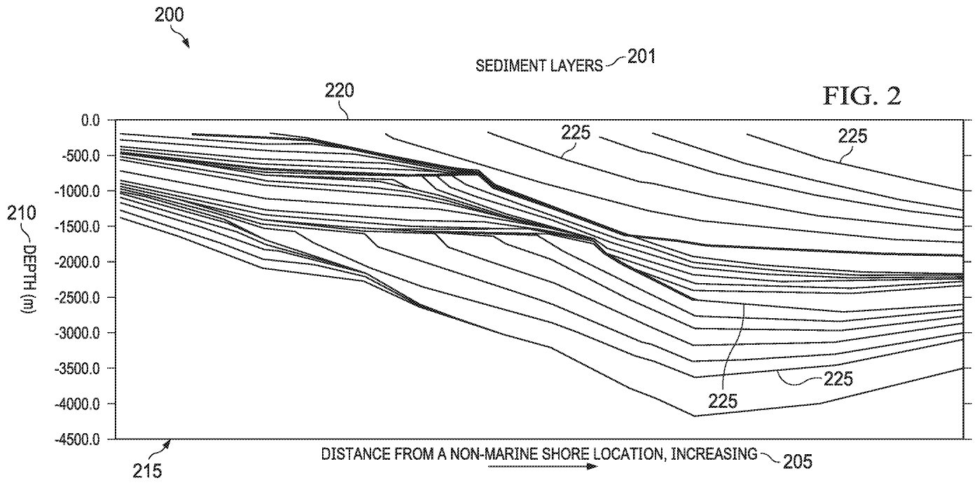

FIG. 3 illustrates an example diagram demonstrating a slope readjustment model;

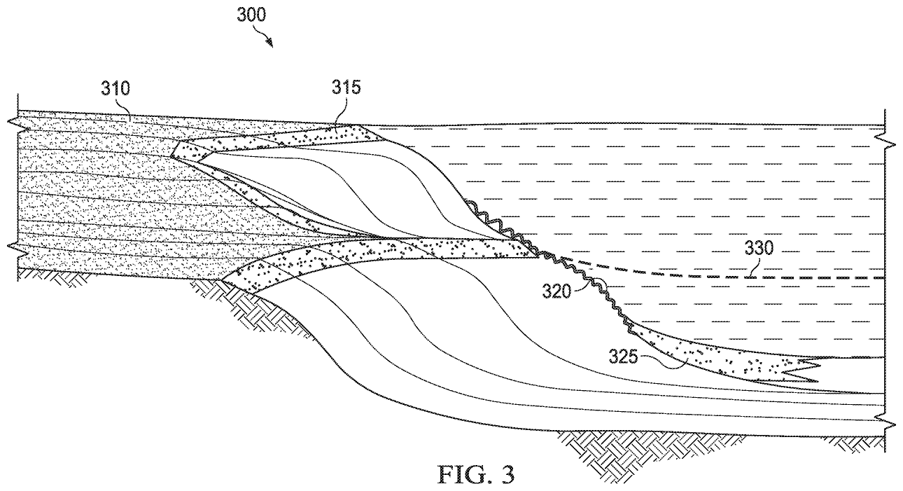

FIG. 4 illustrates an example diagram of a graph demonstrating an out of grade or margin condition;

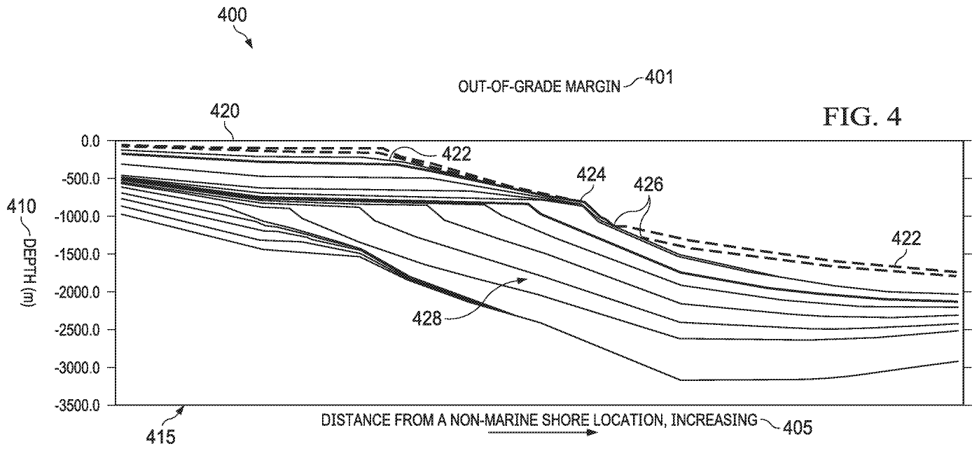

FIG. 5 illustrates a flow diagram of an example method for generating a basin fill model;

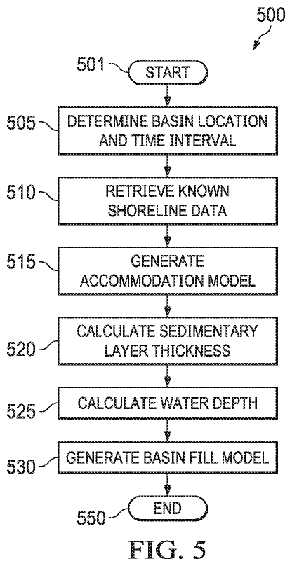

FIG. 6 illustrates a flow diagram, expanding on FIG. 5, of an example method for generating interim models and parameters for a basin fill model;

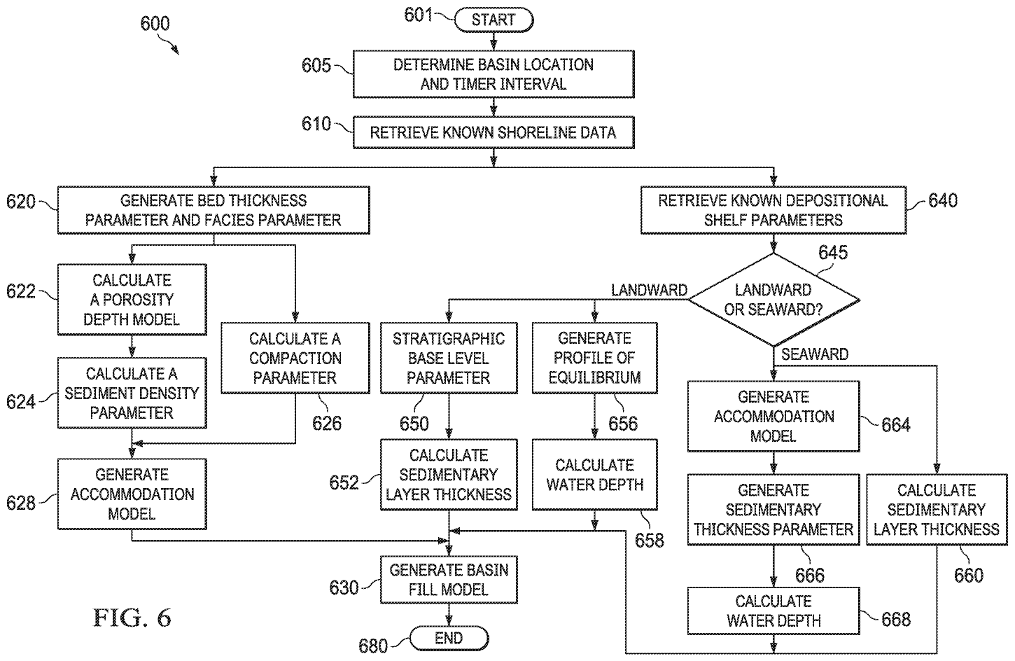

FIG. 7 illustrates a flow diagram of an example method for predicting a submarine fan deposition; and

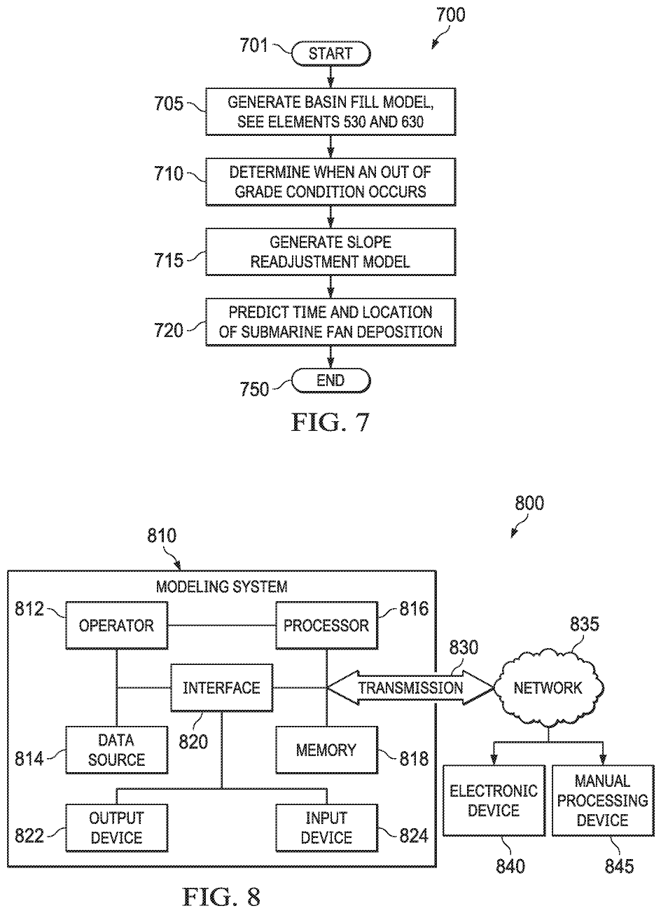

FIG. 8 illustrates a block diagram of an example basin fill modeling system.

### DETAILED DESCRIPTION

Modeling a geographic region, over a geological time interval, i.e. paleogeography, is useful in determining where economically useful material, whether rock, mineral, hydrocarbon, or other types of material, may be located. As the various parts of the Earth move due to various forces, both subsidence and uplift occur. Subsidence is the motion of the Earth's surface as it shifts downward relative to a determined parameter, such as sea level. Uplift results in an increase in elevation of the location relative to a determined parameter.

These forces cause variations in sedimentary basins, which are regions of long-term subsidence creating accommodation space for infilling by sediments. Aspects of the sediment, namely its composition, primary structures, and internal architecture, can be synthesized into a history of the basin fill. Such a synthesis can reveal how the basin formed, how the sediment fill was transported or precipitated, and reveal sources of the sediment fill. As a result, predictions on where valuable materials, such as hydrocarbons and minerals, are located can be made using the synthesis of how the basin was formed over time.

The various processes described herein that cause variations in sedimentary basins can occur over a specified time interval in Earth's history. A time interval can be selected for an identified time period in Earth's history, for example, last year, or 500 to 200 million years ago. The time interval is selected from factors relevant to the basin and to the type of information needed. From the syntheses for the selected time interval, models can be developed to generate a prediction on the types of materials that may be found in the analyzed basin. To analyze sedimentary basins, stratigraphy is used, in which various sedimentary sequences are related to pervasive changes in sea level and sediment supply.

In the industry today, there are several algorithms to model sedimentary basin fill regions (basin locations). Current industry algorithms require multiple iterations to refine the paleogeographic model to a state that can be utilized further by the industry. For example, calculations on shoreline positions can be derived from uncertain, i.e. estimated, input parameters, such as sediment supply, grain-size distribution, marine energy, and other parameters. As a result of this uncertainty, many forward stratigraphic modeling algorithms emphasize sea level changes as their dominant determinant.

Having shoreline characteristics as known parameters for the time intervals being investigated, simplifies the calculations required by the algorithms and results in a more efficient analytical solution. Known shoreline characteristic parameters can also increase the reliability of the results since estimations are removed from the calculations. Shoreline characteristics, for example, positions over time, can be used to generate various models and parameters, such as estimates of depositional shelf edge positions (using shelf width assumptions), an accommodation model, a sedimentary thickness parameter, a water depth parameter, a compaction model, and a slope adjustment model. These models and parameters can then be used in a well system operation plan to assist in predicting where hydrocarbon or mineral deposits of interest may exist, and a cost of recovery can be estimated using the calculated water depths and sedimentary thicknesses. Using the models disclosed herein can be used for the strategic placement of well bores, such as exploration wells, and provide a greater return on investment of drilling. Thus, a well bore can be located and drilled employing the models disclosed herein.

This disclosure relates to geophysical modeling of basin fill algorithms utilizing known shoreline, depositional shelf, bed thickness, and facies characteristic parameters and other known data. Having the known parameters and data can constrain multiple aspects of the basin fill modeling algorithms thereby reducing the complexity of the algorithms, reducing the number of iterations required by the algorithms, and reducing the number of estimations required for the calculations.

As a result of the improved algorithms, as disclosed herein, predictions of where and when commercially important material deposits can be found and relied upon by the industry. The predictions, derived from the results of the disclosed methods, emphasize the slope readjustment model whereby the timing and location of onlapping submarine fan deposits is controlled primarily by the over-steepening of slope margins over time. Determining the paleobathymetry over the time interval allows the above predictions to be made for submarine fan depositions.

An overall basin fill model is generally comprised of multiple interim-models that, when combined, provide an overall model of the basin fill location and time interval of interest. For example, a gross bed thickness parameter and a compaction model can be used to derive an accommodation model. A sedimentary layer thickness parameter can be derived from known shoreline/depositional shelf edge positions proximate to the location. And a water depth parameter can be derived for the location over a time interval.

These interim-models can be derived or calculated using various algorithms. Conventional industry algorithms use estimations of shoreline, depositional shelf, bed thickness, and facies characteristics and then perform multiple iterations of the algorithms to refine the models to achieve a state where they can be utilized in further industry processes. This disclosure demonstrates that utilizing known shoreline, depositional shelf, bed thickness, and facies characteristics with conventional industry algorithms reduces algorithm complexity and increases the speed of results and reliability of the resultant models.

A basin fill model can be generated using a set of interim-models and parameters. A specific basin location and time interval of interest is determined. Using the basin location and time interval, an accommodation model is generated. A sedimentary layer thickness parameter can be calculated using information derived from known shoreline characteristics, for example, from a database, where the shoreline position is proximate to the basin location of interest. A water depth parameter can be calculated for the basin location. Combining the interim-models and parameters can generate an overall basin fill model. The known data used for the above steps can reduce the complexity and therefore can increase the speed of achieving results and reliability of the resultant models.

The accommodation model can be generated from known bed thickness parameters and known facies parameters. The known parameters can be derived from a data source, for example, a proprietary database of shoreline information.

In other examples, the basin location is determined relative to a depositional shelf edge (calculated from shoreline position database), i.e. either seaward or landward. Depositional shelf characteristics, of which the shelf edge is one such parameter, can be retrieved as known data parameters from a database. The depositional shelf edge position is the effective depositional limit of active, wave-graded, deposition in a basin ward direction and is a determined distance from a specified point of the shoreline. The sedimentary layer thickness parameters and water depth parameters can be calculated using the relative position of the depositional shelf edge. The relative position of the depositional shelf edge can be used to apply appropriate known parameters to the algorithmic calculation processes used for conventional modeling. Such known parameters can be, for example, a stratigraphic base level parameter, shelf-width parameter, a shelf-edge location, a profile of equilibrium, and an accommodation model.

A slope adjustment model can be generated for the basin fill model. The slope adjustment model can be utilized to predict where and when a submarine fan deposition will be located in an area or region. Certain submarine fans can contain valuable materials, for example, minerals and hydrocarbons that are of commercial interest.

Various non-transitory computer readable medium embodiments are disclosed that can retrieve known shoreline, depositional shelf, bed thickness, and facies characteristics, and other known data, and utilize that data in combination with other derived information to generate an accommodation model, a sedimentary layer thickness parameter, a water depth parameter, and an overall basin fill model.

The disclosure also provides a basin fill modeling system including a data source, for example a database, which stores various known characteristic parameters, such as shoreline, depositional shelf, bed thickness, and facies parameters, and other known data about the basin location. It can also include an operator, an interface, and a processor, which can execute the algorithms using the data received for the basin location and retrieved from the data source.

The examples used in this disclosure use a sea based environment, but the disclosure can be equally applied to land based, i.e. fresh water, regions.

Turning now to the figures, FIG. 1A illustrates an example diagram 100 demonstrating a basin profile of equilibrium for a non-marine and shallow marine environment. Diagram 100 includes a non-marine area 110 (dark shading), a shoreline area 120 (medium shading), a subaqueous delta platform 121 (light shading), depositional shelf edge 122, drowned continental shelf 123, sea floor 124, and a pre-existing sedimentary layer 125. Average sea level is marked by the solid line 113 and the average wave base is marked with dashed line 116.

As an example of the processes involved that cause variations in sedimentary basins, wave action can create movement of materials relative to the shoreline 120 and the subaqueous delta platform 121 causing an increase in sediments moving from those areas to further away from the shoreline 120, thereby moving the depositional shelf edge 122 to the right in FIG. 1A. In an alternative example, the wave action can shrink the depositional shelf, thereby moving the depositional shelf edge 122 to the left in FIG. 1A, closer to the shoreline 120. In the examples, the sediments deposited can shift inward or outward relative to the shoreline, and increase or decrease in thickness. In addition, the changes in sediments can be different during different time periods. In this example, shoreline 120 characteristics, which include the subaqueous delta platform 121, and the depositional shelf edge 122 characteristics are known data parameters for a given time period.

FIG. 1B illustrates an example diagram 140 demonstrating a basin profile of equilibrium propagating into a deep marine environment. Diagram 140 includes sediment layers 150, shoreline 160, depositional shelf edge 162, and slope and basin profile of equilibrium 166. Average sea level is marked by solid line 153 and the average wave base is marked by dashed line 156.

In diagram 140, the lines running through the sediments 150 show an example sedimentary layering with various thicknesses. As the wave action moves sediments, the number of sediment layers and the thickness of each layer can change over time, either increasing or decreasing in amount. By having known parameters and characteristics for the shoreline, depositional shelf, and other paleogeographic information across a variety of time periods, the models needed for well system operation plans are simplified.

FIG. 2 illustrates an example diagram 200 of a generated basin fill model graph 201 demonstrating sedimentary layers extending under sea level. The graph 201 includes an x-axis 205 showing a relative distance from a shoreline position 215 and a y-axis 210 showing the relative depth of each sedimentary layer 225 in meters below sea level. Line 220 shows an approximate sea level position.

Graph 201 is showing the results of an example basin fill model where the sedimentary layers, shown by 225, change in thickness and depth as the distance increases from the shoreline position 215. Knowing this information can increase the prediction reliability on where valuable hydrocarbons or minerals may be located.

FIG. 3 illustrates an example diagram 300 demonstrating a slope readjustment model and active sediment movements. Diagram 300 includes non-marine area 310, shoreline area 315, sediment bypass area 320, submarine fan deposition 325, and a predicted graded margin profile 330 (shown as a dashed line).

The known shoreline characteristics for the shoreline area 315 can be used to increase the accuracy of calculating the sediment readjustment model for the sediment bypass area 320 since estimations will not be used. The generated models can be used to determine when a margin is out of grade or over steepened with respect to an equilibrium profile.

The known shoreline characteristics and other known paleogeographic data can therefore be used to predict the final graded margin profile 330, i.e. where the sediment movement reaches a point of equilibrium. In addition, the prediction for the final graded margin profile 330 can include a prediction of the time period and location of the submarine fan deposition 325, under how many layers of sediment the submarine fan deposition 325 is located, and the thickness of each of those sedimentary layers. In addition, the composition of the submarine fan deposition can be predicted, such as an estimation of the amount of hydrocarbons or minerals.

FIG. 4 illustrates an example diagram 400 of a graph 401 demonstrating a basin fill model with an out of grade or margin condition. Such out of grade models can assist in the prediction of submarine fan depositions where the time period and location of such depositions can be identified from known shoreline and deposition characteristic parameters.

Graph 401 includes and x-axis 405 indicating an increasing distance from an identified shoreline position 415 and a y-axis 410 indicating a relative depth below an average sea level, in meters, for each of the sedimentary layers. Line 420 indicates an average sea level position for the graph 401. Dashed lines 422 indicate a predicted graded slope profile of equilibrium. Point 424 indicates a region of sediment bypass. Points 426 indicate regions of on-lapping fan and apron deposits. Lines 428 indicate various layers of sedimentary deposits and relative thicknesses for each deposited layer.

Graph 401 is demonstrating a method that, through the known shoreline and depositional shelf characteristic parameters, can restore the bathymetry though time, i.e. can model how the sea has changed water depth over a time period. With this information, the basin fill modeling system can also predict when and where it is more likely that sediment bypass occurs and submarine fan depositions are located.

FIG. 5 illustrates a flow diagram of an example method 500 for generating a basin fill model. The method 500 begins at a step 501 and proceeds to a step 505. Step 505 determines a basin location of interest, i.e. where a decision has been made to investigate this basin location. Step 505 also determines a time period for the resultant modeling. Time periods can be measured using an available metric, for example, time periods can be stated as 400 million years ago to 100 million years ago, 50 million years ago to 1 million years ago, or 50,000 years ago to the present day.

Proceeding to a step 510, known shoreline characteristic parameters, known depositional shelf edge characteristic parameters (calculated from a shoreline database), and other known paleogeographic characteristic parameters are retrieved from a data source, such as a database. Since the various characteristic parameters are known from a data source, the algorithms and models applied to generate the basin fill model have an increased accuracy, reliability, and a reduced complexity to resolve. The models generated under the disclosed methods, do not require the number of algorithmic iterations normally required when estimations of the characteristic parameters are made.

Proceeding to a step 515, an accommodation model is generated using the known characteristic parameters retrieved from the data source. In a step 520, the sedimentary layer thickness is calculated using the known characteristic parameters. In a step 525, the average water depth for the time period is calculated using the known characteristic parameters.

Proceeding to a step 530, a basin fill model is generated. The method ends at a step 550. The basin fill model can be used in a prediction of where and when a submarine fan deposition may occur and in estimating the hydrocarbon or mineral content of such a submarine fan deposition. The basin fill model can also be used to assist in planning or modifying a well system operation plan. These applications can be combined to provide broader information for well system operation planning.

FIG. 6 illustrates a flow diagram, expanding on method 500, of an example method 600 for generating interim-models and parameters for a basin fill model. The method begins at a step 601 and proceeds to a step 605 to determine a basin location and a time period of interest for further investigation. As in method 500, the time period can be an identifiable time period.

Proceeding to a step 610, known shoreline characteristic parameters, known depositional shelf characteristic parameters, and other known paleogeographic characteristics are retrieved from a data source, such as known bed thickness characteristics and known facies characteristics. As in method 500, the known characteristic parameters can reduce the complexity and iterations required for the applied algorithms while increasing the reliability of the results.

Proceeding from step 610 are two paths that can be executed in an order or simultaneously, a step 620 and a step 640. Step 620 generates, for the basin location, bed thickness parameters and facies parameters from the known characteristic parameters. Proceeding to a step 622, a porosity depth model can be generated from the data generated in the previous step 620. In a step 624, sediment density parameters can be calculated from the proceeding steps' calculations.

Also from step 620, the method can proceed to a step 626 to calculate compaction parameters. Proceeding to a step 628, the resultant calculations from steps 624 and 626 can be used to generate an accommodation model.

Returning to step 610 and proceeding to step 640, the depositional shelf characteristic parameters will be utilized. At a decision step 645, the basin location is compared to a proximate depositional shelf location and a determination is made whether the basin location is landward or seaward of the depositional shelf. The relative positioning of the basin location to the depositional shelf controls the type of algorithms applied to the calculations.

If the basin location is landward of the depositional shelf location, then the method proceeds to a step 650 where stratigraphic base level parameters are calculated. Proceeding to a step 652, the sedimentary layer thickness is calculated. In a step 656, the profile of equilibrium can be calculated. In a step 658, the water depth parameters can be calculated.

If the basin location is seaward of the depositional shelf location, then the method proceeds to a step 660 to calculate the sedimentary layer thickness parameters. A step 664 can be executed to generate a water depth accommodation model. Proceeding to a step 666, a second set of sedimentary thickness parameters can be calculated specifically toward calculating a water depth parameter. Proceeding to a step 668, the water depth parameters are calculated using the parameters from the previous steps.

From steps 628, 652, 658, 660, and 668, the method proceeds to a step 630. Step 630 waits until the necessary previous steps have completed to the point where step 630 can generate a basin fill model using the generated models and calculated parameters from the previous steps. Not all previous steps need to or can be completed for step 630 to proceed. The method ends at a step 680.

FIG. 7 illustrates a flow diagram of an example method 700 for predicting a submarine fan deposition. Starting at a step 701 and proceeding to a step 705, the method begins with the generation of a basin fill model, for example, the basin fill model generated at step 530 or step 630. The method 700 proceeds to a step 710 where an out of grade or margin condition is determined for the basin location. Proceeding to a step 715, a slope readjustment model is generated.

At a step 720, a prediction can be made on where and when a submarine fan deposition will occur proximate to the basin location. The submarine fan deposition region can include hydrocarbons, minerals, and other valuable material for well operations to retrieve. The reliability of the prediction of where such a deposition lies can reduce the cost of exploring the region and assist in developing a well system operation plan. A depositional region can extend for a large distance, for example, 300-500 kilometers from a designated shore reference point. Narrowing a location for well operations, including, exploration operations, would be beneficial to the industry. The method ends at a step 750.

FIG. 8 illustrates a block diagram 800 of an example modeling system 810, such as a basin fill modeling system or a submarine fan deposition prediction modeling, and other types of well system operation modeling systems. The methods described herein can be executed on modeling system 810. Modeling system 810 includes operator 812, data source 814, processor 816, memory 818, interface 820, output device 822, and input device 824. These components may be combined or separated, in various combinations, as needed for an implementation. These components may exist localized in a single system or be separated a distance from each other in multiple systems, wherein each of the components are communicatively coupled to the other system components. For example, data source 814 can exist in a database located a distance away from the other system components, but communicatively coupled so that the other components can retrieve appropriate and necessary data from data source 822.

Modeling system 810 is communicatively coupled to a network 835 through transmission 830. Network 835 can be a network of various types, such as a wired, wireless, or other type of network. The network 835 is further communicatively coupled with other systems and devices, such as electronic devices 840 and manual processing devices 845. Device 840 can be a single device, for example, a laptop, smartphone, or other device, or device 840 can represent systems of devices, for example a separate data center or cloud based environment. The network 835 can also be communicatively coupled to manual processing devices 845, for example, a paper printer, a three dimensional (3D) modeling printer, a monitor, or other types of devices that can be interacted with by humans.

Operator 812 is configured to send and receive data elements and information from other systems and to retrieve a set of data parameters, using the data elements, from the data source 814. The data elements received can be, for example, a location of a basin of interest and a time period or interval of interest. The operator 812 can control the other modeling system 810 components, direct their operation, and control communications with other systems.

Data source 814 includes known paleogeographic data that is known to the entity executing the methods described herein, where the entity can be a human, corporation, or other type of entity. The paleogeographic data can include known shoreline characteristic parameters, known depositional shelf characteristic parameters, known bed thickness characteristic parameters, and known facies characteristic parameters for multiple locations over multiple time periods. A location can be a physical location, for example the Gulf of Mexico or a continental shelf off the coast of a country. The time period can be an identified time period, for example, 500 million years ago to 300 million years ago, or 10,000 years ago to the present day. Since the data source 814 includes known data elements, the models and algorithms executed by processor 816 can be less complex, contain fewer iterations, and fewer estimations, which can result in a higher reliability of the results.

Processor 816 is capable to execute methods and algorithms to generate or calculate various models and parameters. For example, the processor 816 can determine a relative depositional shelf position to a basin location. The basin location can be landward, i.e. closer to a shoreline location than the depositional shelf, or seaward, i.e. farther from a shoreline location than the depositional shelf. The models used differ on the basin location relative to the depositional shelf.

Processor 816 can also generate a set of interim models and parameter values using the data parameters retrieved from data source 814 and the data elements received from another system. For example, the interim models and data parameters can include an accommodation model, a slope readjustment model, a porosity-depth model, a water depth parameter, a sedimentary thickness parameter, a compaction parameter, and a sediment density parameter. Processor 816 can also generate a basin fill model using the previously generated interim models and calculated parameter values. In addition, processor 816 can generate a prediction model of where and when a submarine fan deposition can be found and thereby provide guidance to well operations. The processor 816 can employ conventional modeling methods that are modified to employ the known data parameters from the data source 814.

Memory 818 is capable to store the data elements, information, characteristic parameters, operating instructions, algorithms, and programming logic. Interface 820 is capable of communicating with one or more systems through communication transmission 830. For example, interface 820 can communicate with a network 835 which in turn can communicate with another electronic device 840 or processing device 845. The interface 820 can also communicate with output device 822 and input device 824, if they are present. Output device 822 is an optional component and can include, for example, a monitor, paper printer, 3D printer, or other devices. Input device 824 is an optional component and can be a device that can provide input data or instructions to the modeling system 810. For example, input device 824 can be a keyboard, mouse, touchscreen, scanner, or other types of input devices.

A portion of the above-described apparatus, systems or methods may be embodied in or performed by digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein.

Portions of disclosed embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floptical disks; and hardware devices that are specially configured to store and execute program code, such as ROM and RAM devices. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, a limited number of the exemplary methods and materials are described herein.

It is noted that as used herein and in the appended claims, the singular forms “a”, “an”, and “the” include plural referents unless the context clearly dictates otherwise.

Aspects disclosed herein include:

A. A method of generating a basin fill model for a basin location comprising, retrieving, from a data source, a set of known shoreline characteristic parameters using a time interval and a basin location; generating a first accommodation model using a bed thickness parameter and a facies parameter at the basin location for the time interval; determining a first sedimentary layer thickness parameter using the set of known shoreline characteristic parameters; determining a water depth parameter at the basin location for the time interval; and generating a basin fill model using the first accommodation model, the first sedimentary layer thickness parameter, and the water depth parameter.
B. A computer program product having a series of operating instruction stored on a non-transitory computer-readable medium that direct a data processing apparatus when executed thereby to perform operations comprising, receiving a time interval and a first basin location; retrieving, from a data source, a set of known characteristic parameters, including known shoreline, depositional shelf, bed thickness, and facies parameters, where the set of known characteristic parameters are for a location proximate to the first basin location and for the time interval; and generating an accommodation model using the first basin location, the time interval, and the set of known characteristic parameters.
C. A basin fill modeling system, comprising, a processor; a data source comprising multiple known paleogeographic characteristic parameters for multiple locations over multiple time periods; a non-transient storage medium having a computer program product stored therein, the computer program product, when executed, causing the processor to: determine a relative basin location to a depositional shelf position using a set of data parameters from the data source and data elements associated with the known paleogeographic characteristic parameters; calculate a set of interim models and parameter values using the set of data parameters and the data elements; and generate a basin fill model using the set of interim models and parameter values.

Each of aspects A, B, and C can have one or more of the following additional elements in combination:

Element 1: wherein the bed thickness parameter and the facies parameter are generated using the set of known shoreline characteristic parameters. Element 2: calculating a sediment density parameter, using a porosity-depth model generated from the facies parameter. Element 3: calculating a compaction parameter, using the bed thickness parameter. Element 4: retrieving a set of known depositional shelf characteristic parameters, calculated using the time interval and the basin location, from the data source, where the data source includes shoreline position data, and where the basin location is relatively positioned landward or seaward of a depositional shelf from which the set of known depositional shelf characteristic parameters is derived. Element 5: wherein the determining the first sedimentary layer thickness parameter includes using a stratigraphic base level parameter determined using the set of known shoreline characteristic parameters and the set of known depositional shelf characteristic parameters, where the set of known depositional shelf characteristic parameters relate to a shelf-width and the relative positioning is landward. Element 6: wherein the determining the first sedimentary layer thickness parameter includes using the set of known shoreline characteristic parameters and the set of known depositional shelf characteristic parameters, where the set of known depositional shelf characteristic parameters relate to a shelf-edge position and the relative positioning is seaward. Element 7: wherein the determining the water depth parameter is generated from a profile of equilibrium which is determined using the set of known shoreline characteristic parameters and the set of known depositional shelf characteristic parameters, where the set of known depositional shelf characteristic parameters relate to a shelf-edge and the relative positioning is landward. Element 8: wherein the determining the water depth parameter is generated from a second accommodation model and a second sedimentary thickness parameter, where the second accommodation model and the second sedimentary thickness parameter are generated using the set of known shoreline characteristic parameters and the set of known depositional shelf characteristic parameters, where the set of known depositional shelf characteristic parameters relate to a shelf-edge and the relative positioning is seaward. Element 9: determining a first time period when an out of grade condition occurs at the basin location. Element 10: generating a slope readjustment model using the first time period and the set of known shoreline characteristic parameters. Element 11: predicting a second time period and a second basin location of a submarine fan deposition using the slope readjustment model. Element 12: determining a location of a well bore using the basin fill model. Element 13: calculating, at the time interval, a sedimentary layer thickness parameter and a water depth parameter for the first basin location using the set of known characteristic parameters. Element 14: generating a basin fill model using the accommodation model, the sedimentary layer thickness parameter, and the water depth parameter. Element 15: calculating a sediment density parameter at the first basin location using a porosity-depth model generated from the set of known characteristic parameters. Element 16: calculating a compaction parameter using the set of known characteristic parameters. Element 17: determining a relative depositional shelf position to the first basin location, where the basin location is landward or seaward. Element 18: calculating a sedimentary layer thickness parameter and a water depth parameter using the relative positioning and the set of known characteristic parameters. Element 19: generating a basin fill model using the accommodation model, the sedimentary layer thickness parameter, and the water depth parameter. Element 20: calculating a sediment density parameter at the first basin location using a porosity-depth model generated from the set of known characteristic parameters. Element 21: calculating a compaction parameter using the set of known characteristic parameters. Element 22: determining a relative depositional shelf position to the first basin location, where the basin location is landward or seaward. Element 23: calculating a sedimentary layer thickness parameter and a water depth parameter using the relative positioning and the set of known characteristic parameters. Element 24: determining a first time period when an out of grade condition occurs at the first basin location. Element 25: generating a slope readjustment model using the first time period and using the set of known characteristic parameters. Element 26: predicting a second time period and a second basin location for a submarine fan deposition using the slope readjustment model. Element 27: wherein the processor is operable to predict a basin location of a submarine fan deposition for a time interval. Element 28: wherein the set of interim models and parameter values are at least one of an accommodation model, a slope readjustment model, a porosity-depth model, a water depth parameter, a sedimentary thickness parameter, a compaction parameter, and a sediment density parameter. Element 29: wherein the set of known paleogeographic characteristic parameters are comprised of at least one of a set of known shoreline characteristic parameters, a set of known depositional shelf characteristic parameters, a set of known bed thickness characteristic parameters, and a set of known facies characteristic parameters. Element 30: wherein the data elements include a location of a basin of interest and a time interval of interest.

1. A method of generating a basin fill model for a basin location comprising:
retrieving, from a data source, a set of known shoreline characteristic parameters using a time interval and a basin location;
generating a first accommodation model using a bed thickness parameter and a facies parameter at said basin location for said time interval;
determining a first sedimentary layer thickness parameter using said set of known shoreline characteristic parameters;
determining a water depth parameter at said basin location for said time interval; and
generating a basin fill model using said first accommodation model, said first sedimentary layer thickness parameter, and said water depth parameter.

2. The method as recited in claim 1, wherein said bed thickness parameter and said facies parameter are generated using said set of known shoreline characteristic parameters.

3. The method as recited in claim 1, further comprising:
calculating a sediment density parameter, using a porosity-depth model generated from said facies parameter; and
calculating a compaction parameter, using said bed thickness parameter.

4. The method as recited in claim 1, further comprising retrieving a set of known depositional shelf characteristic parameters, using said time interval and said basin location, from said data source, where said basin location is relatively positioned landward or seaward of a depositional shelf from which said set of known depositional shelf characteristic parameters is derived.

5. The method as recited in claim 4, wherein said determining said first sedimentary layer thickness parameter includes using a stratigraphic base level parameter determined using said set of known shoreline characteristic parameters and said set of known depositional shelf characteristic parameters, where said set of known depositional shelf characteristic parameters relate to a shelf-width and said relative positioning is landward.

6. The method as recited in claim 4, wherein said determining said first sedimentary layer thickness parameter includes using said set of known shoreline characteristic parameters and said set of known depositional shelf characteristic parameters, where said set of known depositional shelf characteristic parameters relate to a shelf-edge position and said relative positioning is seaward.

7. The method as recited in claim 4, where said determining said water depth parameter is generated from a profile of equilibrium which is determined using said set of known shoreline characteristic parameters and said set of known depositional shelf characteristic parameters, where said set of known depositional shelf characteristic parameters relate to a shelf-edge and said relative positioning is landward.

8. The method as recited in claim 4, wherein said determining said water depth parameter is generated from a second accommodation model and a second sedimentary thickness parameter, where said second accommodation model and said second sedimentary thickness parameter are generated using said set of known shoreline characteristic parameters and said set of known depositional shelf characteristic parameters, where said set of known depositional shelf characteristic parameters relate to a shelf-edge and said relative positioning is seaward.

9. The method as recited in claim 1, further comprising:
determining a first time period when an out of grade condition occurs at said basin location;
generating a slope readjustment model using said first time period and said set of known shoreline characteristic parameters; and
predicting a second time period and a second basin location of a submarine fan deposition using said slope readjustment model.

10. The method as recited in claim 1, further comprising determining a location of a well bore using said basin fill model.

11. A computer program product having a series of operating instruction stored on a non-transitory computer-readable medium that direct a data processing apparatus when executed thereby to perform operations comprising:
receiving a time interval and a first basin location;
retrieving, from a data source, a set of known characteristic parameters, including known shoreline, depositional shelf, bed thickness, and facies parameters, where said set of known characteristic parameters are for a location proximate to said first basin location and for said time interval; and
generating an accommodation model using said first basin location, said time interval, and said set of known characteristic parameters.

12. The computer program product as recited in claim 11, said operations further comprising:
calculating, at said time interval, a sedimentary layer thickness parameter and a water depth parameter for said first basin location using said set of known characteristic parameters.

13. The computer program product as recited in claim 12, said operations further comprising:
generating a basin fill model using said accommodation model, said sedimentary layer thickness parameter, and said water depth parameter.

14. The computer program product as recited in claim 11, said operations further comprising:
calculating a sediment density parameter at said first basin location using a porosity-depth model generated from said set of known characteristic parameters; and
calculating a compaction parameter using said set of known characteristic parameters.

15. The computer program product as recited in claim 11, said operations further comprising:
determining a relative depositional shelf position to said first basin location, where said basin location is landward or seaward; and
calculating a sedimentary layer thickness parameter and a water depth parameter using said relative positioning and said set of known characteristic parameters.

16. The computer program product as recited in claim 11, said operations further comprising:
determining a first time period when an out of grade condition occurs at said first basin location;
generating a slope readjustment model using said first time period and using said set of known characteristic parameters; and
predicting a second time period and a second basin location for a submarine fan deposition using said slope readjustment model.

17. A basin fill modeling system, comprising:
a processor;
a data source comprising multiple known paleogeographic characteristic parameters for multiple locations over multiple time periods;
a non-transient storage medium having a computer program product stored therein, said computer program product, when executed, causing said processor to:
determine a relative basin location to a depositional shelf position using a set of data parameters from said data source and data elements associated with said known paleogeographic characteristic parameters;
calculate a set of interim models and parameter values using said set of data parameters and said data elements; and
generate a basin fill model using said set of interim models and parameter values.

18. The basin fill modeling system as recited in claim 17, wherein said processor is operable to predict a basin location of a submarine fan deposition for a time interval.

19. The basin fill modeling system as recited in claim 17, wherein said set of interim models and parameter values are at least one of an accommodation model, a slope readjustment model, a porosity-depth model, a water depth parameter, a sedimentary thickness parameter, a compaction parameter, and a sediment density parameter.

20. The basin fill modeling system as recited in claim 17, wherein said set of known paleogeographic characteristic parameters are comprised of at least one of a set of known shoreline characteristic parameters, a set of known depositional shelf characteristic parameters, a set of known bed thickness characteristic parameters, and a set of known facies characteristic parameters.

21. The basin fill modeling system as recited in claim 17, wherein said data elements include a location of a basin of interest and a time interval of interest.
